(19) United States
(12) Patent Application Publication
(10) Pub. No.: US 2026/0313828 A1
(43) Pub. Date: Oct. 8, 2026

(54) Information Handling System Having Mount System with a Blank Module Having an Integrated Air Flow Component

(71) Applicant: Dell Products L.P., Round Rock, TX (US)

(72) Inventors: David L. Roper, Austin, TX (US); Megan Wingfield, Dalzell, SC (US); Emily Clark, Round Rock, TX (US)

(21) Appl. No.: 19/171,284

(22) Filed: Apr. 6, 2025

(51) Int. Cl. H05K 7/20; G06F 1/20

(52) U.S. Cl. CPC H05K 7/20145; G06F 1/20

(57) ABSTRACT

A system and method for providing an information handling system with a mount system having an integrated thermal component. The mount system includes a plurality of connector receptacles, each of the plurality of connector receptacles being configured to receive a respective memory module, the plurality of connector receptacles being positioned to arrange the respective memory modules in an array; and, a blank system, the blank system comprising a blank module, the module being configured to mount to a connector receptacle of the plurality of connector receptacles; and, an integrated thermal component mechanically attached to the blank module, the integrated thermal component being positioned to avoid touching a memory module when the memory module is installed in the mount system.

### BACKGROUND OF THE INVENTION

### Field of the Invention

The present invention relates to information handling systems. More specifically, embodiments of the invention relate to memory connectors used within information handling systems.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY OF THE INVENTION

A system and method are disclosed for providing an information handling system with a mount system having blank module with an integrated air flow component.

More specifically, in one embodiment the invention relates to a blank system for use with a memory system of an information handling system, comprising: blank module, the module being configured to mount to a connector receptacle of a memory mount system; and, an integrated thermal component mechanically attached to the blank module, the integrated thermal component being positioned to avoid touching a memory module when the memory module is installed in the mount system.

In another embodiment the invention relates to a mount system comprising: a plurality of connector receptacles, each of the plurality of connector receptacles being configured to receive a respective memory module, the plurality of connector receptacles being positioned to arrange the respective memory modules in an array; and, a blank system, the blank system comprising a blank module, the module being configured to mount to a connector receptacle of the plurality of connector receptacles; and, an integrated thermal component mechanically attached to the blank module, the integrated thermal component being positioned to avoid touching a memory module when the memory module is installed in the mount system.

In another embodiment the invention relates to a system comprising: a processor; a data bus coupled to the processor; and a mount system comprising: a plurality of connector receptacles, each of the plurality of connector receptacles being configured to receive a respective memory module, the plurality of connector receptacles being positioned to arrange the respective memory modules in an array; and, a blank system, the blank system comprising a blank module, the module being configured to mount to a connector receptacle of the plurality of connector receptacles; and, an integrated thermal component mechanically attached to the blank module, the integrated thermal component being positioned to avoid touching a memory module when the memory module is installed in the mount system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a mount system configured with a plurality of connector receptacles.

FIGS. 3A, 3B and 3C, generally referred to as FIG. 3, show views of portions of a mount system having a plurality of connector receptacles.

FIG. 4 shows a blank module with an integrated air flow component.

FIG. 5 shows a side view of a mount system configured with a memory module and a blank module with an integrated air flow component.

FIG. 6 shows a side view of a mount system configured with a plurality of memory modules and a plurality of blank modules with integrated air flow components.

FIG. 7 shows a side view of a mount system configured with a plurality of memory modules and a plurality of blank modules with integrated air flow components.

FIGS. 8A, 8B and 8C, generally referred to as FIG. 8, show views of a blank module with integrated air flow components.

### DETAILED DESCRIPTION

A system and method are disclosed for providing an information handling system with a mount system having a blank module with an integrated air flow component.

Various aspects of the disclosure reflect an appreciation that implementing an air flow geometry component between memory modules improves the thermal performance of the memory modules. Various aspects of the present disclosure include an appreciation that it is known to mount a plurality of memory modules within a mount system. Various aspects of the present disclosure include an appreciation that it is known to mount blank modules in unoccupied connector receptacles within a mount system. As used herein, a blank module broadly refers to a component which does not include any electronics and is configured with a form factor designed to mount with a connector receptacle of a mount system when a memory module is not installed in the connector receptacle. Various aspects of the present disclosure include an appreciation that blank modules can be used to fill open slots of the mount system to improve air flow within the mount system.

Various aspects of the present disclosure include an appreciation that it is known to implement air flow geometry components with a spiraling geometry. Various aspects of the present disclosure include an appreciation that known to air flow geometry components are often implemented to be connected directly to a memory module or to be positioned between pairs of memory modules, sometimes via a twisted tape type component.

A system and method are disclosed for providing a blank module with an integrated thermal component. In certain embodiments, the integrated thermal component is integrated into a blank module of a mount system. In certain embodiments, such an integrated thermal component expands a thermal component implementation to include a thermal component implementation which can be provided via a system supplier when the system is shipped or at a later date, via a blank vendor, via a thermal solutions provider, etc.

In certain embodiments, the thermal component includes an integrated air flow geometry. In certain embodiments, the air flow geometry includes a spiraling air flow geometry. In certain embodiments, the thermal component is structurally included with a blank module rather than being connected directly to the memory module.

In certain embodiments, the thermal component is provided to be attached by a consumer to the blank module itself. In certain embodiments, the thermal component is molded or attached to the body of the blank module. In certain embodiments, the thermal component may be offered as a thermal high-performance blank product by a system supplier, a blank vendor, a thermal solutions provider, etc.

In various embodiments, the thermal component is molded into, attached to, or attachable to a body of the blank module. In certain embodiments, the thermal component can be offered as a thermal high-performance product from a system supplier, a blank vendor, a thermal solutions provider, etc. In certain embodiments, the thermal component can be attached before or after memory modules are installed in a mount system. Providing such an attachment option facilitates future upgraded air flow components, an easy ability to accommodate memory module pitch variations and allows repairability in the field or factory.

In various embodiments, the thermal component can be implemented on either or both sides of the blank module. In various embodiments, thermal component configuration provides an ability to add double sided cooling to memory locations that previously could not have had coverage on both sides of the memory components.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

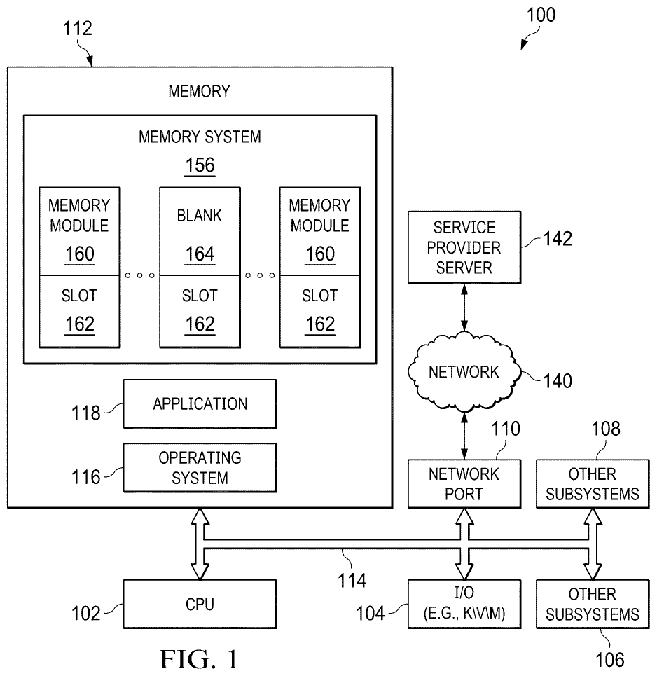

FIG. 1 is a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, a touchpad or touchscreen, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116 and in various embodiments may also comprise an application 118. In one embodiment, the information handling system 100 is able to download the application 118 from the service provider server 142. In another embodiment, the application 118 is provided as a service from the service provider server 142.

In various embodiments, the system memory 112 includes a memory system 150 coupled to processor 102. In various embodiments, the memory system 150 may include RAM, EEPROM, a PCMCIA card, flash memory, magnetic storage, opto-magnetic storage, or any suitable selection and/or array of volatile or non-volatile memory. In various embodiments, some or all of the components of the memory system 150 retain data after power to information handling system 102 is removed.

In certain embodiments, the memory system 150 includes a plurality of memory slots 162, each configured to receive a corresponding memory module 160 or a corresponding blank module 164. A memory slot 162 may include any system, device, or apparatus configured to receive a memory module 160 to physically, electrically, or a combination thereof, the memory module 160 to the processor 102. Each memory module 160 includes a system, device or apparatus configured to retain program instructions and/or data (e.g., computer-readable media). In certain embodiments, each memory module 160 includes one or more of a dynamic random access memory (DRAM) module (e.g., a dual in-line package (DIP) memory, a Single In-line Pin Package (SIPP) memory, a Single-Inline Memory Module (SIMM), a Dual-Inline Memory Module (DIMM), a Ball Grid Array (BGA)), or any other suitable memory.

In certain embodiments, one or more memory module slots are configured with blank module. In certain embodiments, the blank module is provided with an integrated thermal component. In certain embodiments, the integrated thermal component is integrated into a blank module of a mount system. In certain embodiments, such an integrated thermal component expands a thermal component implementation to include a thermal component implementation which can be provided via a system supplier, a blank vendor, a thermal solutions provider, etc.

In certain embodiments, the thermal component includes an integrated air flow geometry. In certain embodiments, the air flow geometry includes a spiraling air flow geometry. In certain embodiments, the thermal component is structurally included with a blank module rather than being connected directly to the memory module.

In certain embodiments, the thermal component is provided to be attached by a consumer to the blank module itself. In certain embodiments, the thermal component is molded or attached to the body of the blank module. In certain embodiments, the thermal component may be offered as a thermal high-performance blank product by a system supplier, a blank vendor, a thermal solutions provider, etc.

In various embodiments, the thermal component is molded into, attached to, or attachable to a body of the blank module. In certain embodiments, the thermal component can be offered as a thermal high-performance product from a system supplier, a blank vendor, a thermal solutions provider, etc. In certain embodiments, the thermal component can be attached before or after memory modules are installed in a mount system. Providing such an attachment option facilitates future upgraded air flow components, an easy ability to accommodate memory module pitch variations and allows repairability in the field or factory.

In various embodiments, the thermal component can be implemented on either or both sides of the blank module. In various embodiments, thermal component configuration provides an ability to add double sided cooling to memory locations that previously could not have had coverage on both sides of the memory components.

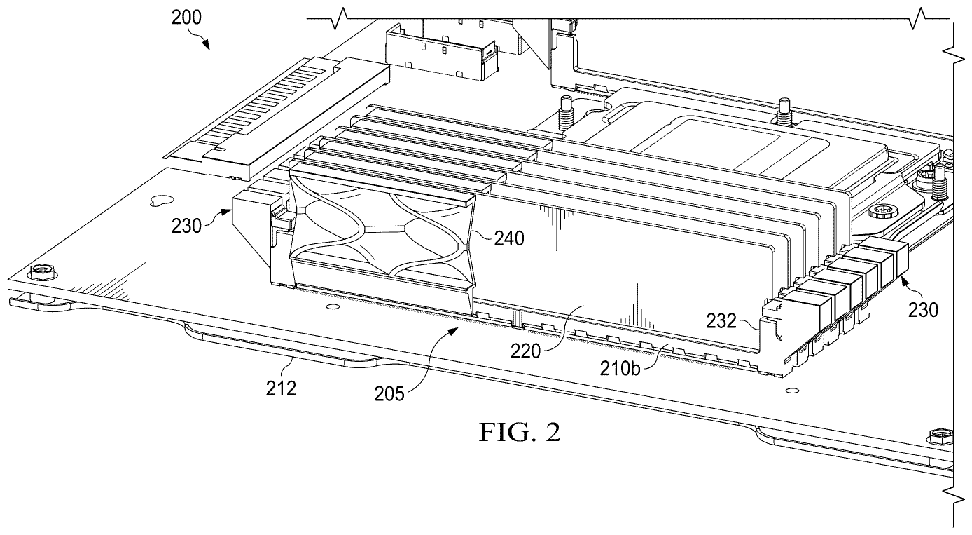

FIG. 2 shows a perspective view of a portion of an information handling system 200 having a mount system 230. In certain embodiments, the mount system 200 includes a plurality of connector receptacles 210. In certain embodiments, the mount system 230 is included within a memory system such as memory system 150.

In certain embodiments, the connector receptacles 210 are mechanically coupled to a circuit board 212 of the information handling system. In certain embodiments, the connector receptacles 210 are configured to receive a corresponding memory module 220, a corresponding blank module 222, or a combination thereof. In certain embodiments, each memory module 220 includes a corresponding DIMM. In certain embodiments, each memory module 220 corresponds to a memory module 160. In certain embodiments, each connector receptacle 210 corresponds to a slot 162. In certain embodiments, only some of the connector receptacles 210 of the mount system 200 have corresponding memory modules 220 mounted therein. Other connector receptacles 220 may have blank modules 222 mounted therein or may be empty.

In certain embodiments, the connector receptacles 210 are positioned such that corresponding memory modules 220, blank modules 222, or a combination thereof, are arranged in an array. In certain embodiments, each connector receptacle 210 includes a first side connector receptacle and a second side connector receptacle 210b. In certain embodiments, each connector receptacle 210 includes one or more latching mechanisms 230. In certain embodiments, the latching mechanisms 230 are located on one edge of the connector receptacle 210 or on both ends of the connector receptacle 210. In certain embodiments, each connector receptacle 210 includes one or more guide elements 232. In certain embodiments, the guide elements 232 are located on one edge of the connector receptacle 210 or on both ends of the connector receptacle 210. In certain embodiments, the guide elements 232 are positioned such that a contact portion of a memory module 220 is guided to couple with a connector receptacle 210 as the memory module 220 is inserted into the connector receptacle 210.

In some embodiments, the connector receptacles 210 are positioned to allow a mechanical accessory (e.g., thermal component 240) to be positioned between memory modules 220 and blank module 222. For example, as shown in FIG. 2, a thermal component 240 may be positioned between a memory modules 220 and a blank module 222 to improve cooling of the memory modules 220. In certain embodiments, a thermal component 240 may be integrated with a blank module 222.

While FIG. 2 shows a thermal component 240 extending across a portion of a blank module 222, one of ordinary skill in the art would understand the thermal inserts 240 may extend across any or all of the corresponding blank module 222. Accordingly, the blank module 222 may be positioned to align and constrain a thermal component 240 during installation and normal use of the memory modules such that thermal component 240 may avoid touching and/or damaging adjacent memory modules 220.

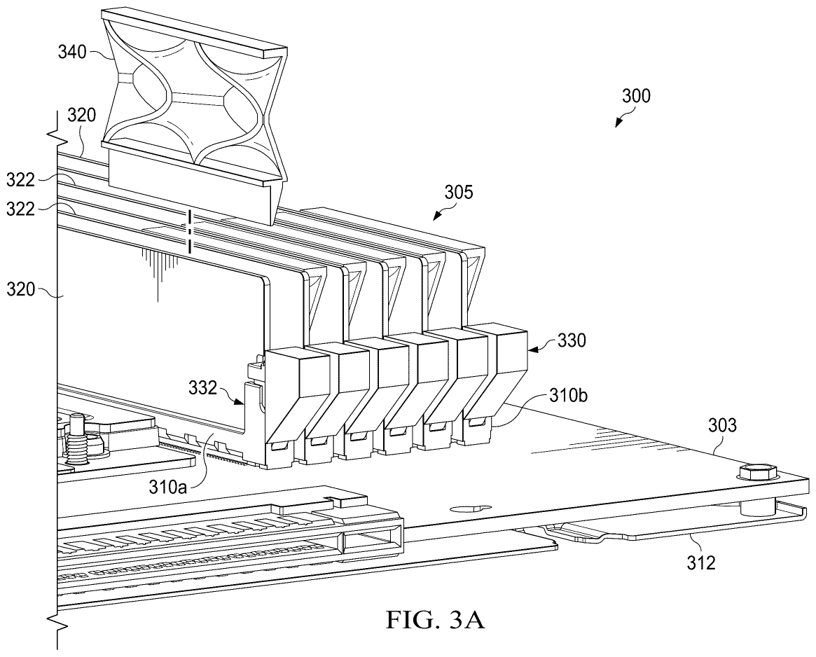

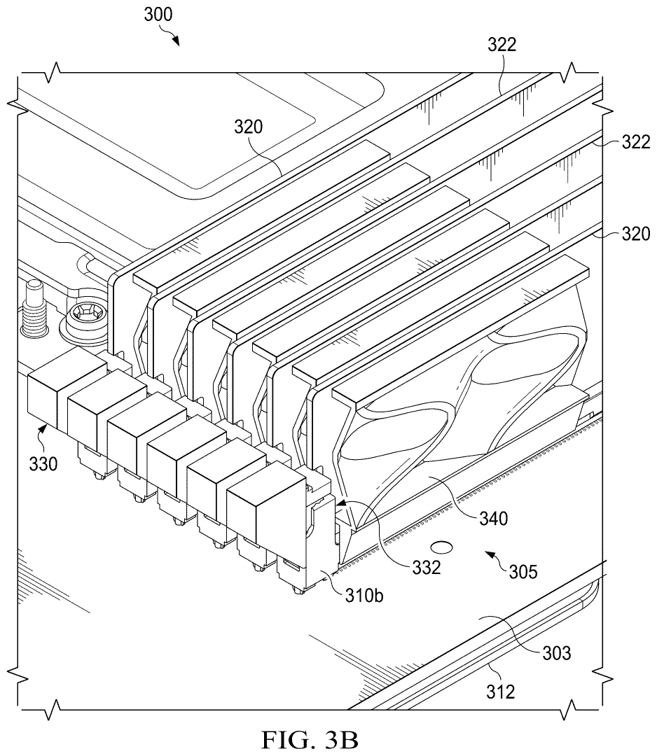

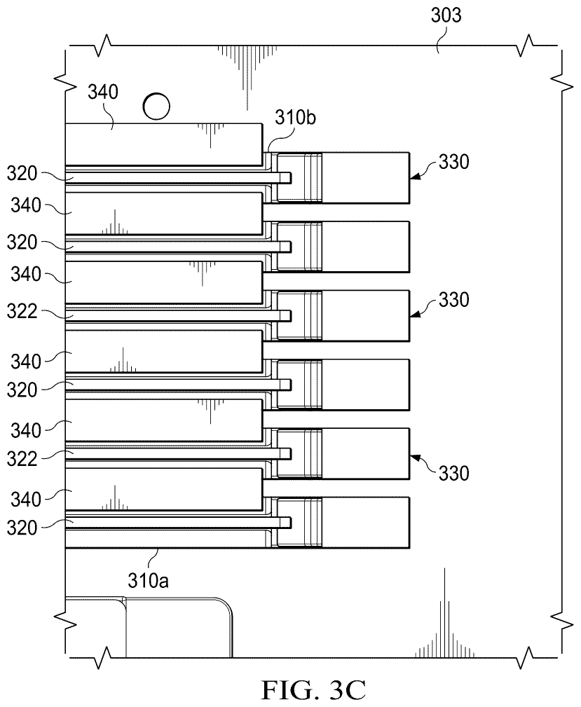

FIGS. 3A, 3B and 3C, generally referred to as FIG. 3, show views of portions of a mount system 300 having a plurality of connector receptacles. More specifically, FIG. 3A shows a front perspective view of a portion a mount system having a plurality of connector receptacles. FIG. 3B shows a rear perspective view of a portion a mount system 300 having a plurality of connector receptacles. FIG. 3C shows a top view of a portion a mount system 300 having a plurality of connector receptacles. In certain embodiments, the mount system 300 is included within a memory system such as memory system 150.

In certain embodiments, the connector receptacles 310 are mechanically coupled to a circuit board 312 of the information handling system. In certain embodiments, the connector receptacles 310 are configured to receive a corresponding memory module 320, a corresponding blank module 322, or a combination thereof. In certain embodiments, each memory module 320 includes a corresponding DIMM. In certain embodiments, each memory module 320 corresponds to a memory module 160. In certain embodiments, each connector receptacle 310 corresponds to a slot 162. In certain embodiments, only some of the connector receptacles 310 of the mount system 300 have corresponding memory modules 320 mounted therein. Other connector receptacles 320 may have blank modules 322 mounted therein or may be empty.

In certain embodiments, the connector receptacles 310 are positioned such that corresponding memory modules 320, blank modules 322, or a combination thereof, are arranged in an array. In certain embodiments, each connector receptacle 310 includes a first side connector receptacle and a second side connector receptacle 310b. In certain embodiments, each connector receptacle 310 includes one or more latching mechanisms 330. In certain embodiments, the latching mechanisms 330 are located on one edge of the connector receptacle 310 or on both ends of the connector receptacle 310. In certain embodiments, each connector receptacle 310 includes one or more guide elements 332. In certain embodiments, the guide elements 332 are located on one edge of the connector receptacle 310 or on both ends of the connector receptacle 310. In certain embodiments, the guide elements 332 are positioned such that a contact portion of a memory module 320 is guided to couple with a connector receptacle 310 as the memory module 320 is inserted into the connector receptacle 310.

In some embodiments, the connector receptacles 310 are positioned to allow a mechanical accessory (e.g., thermal component 340) to be positioned between a memory module 320 and blank module 322. For example, as shown in FIG. 3, a thermal component 340 may be positioned between a memory module 320 and a blank module 322 to improve cooling of the memory modules 320. In certain embodiments, the thermal component 340 is integrated with a blank module 322. For illustration purposes, the thermal component 340 is shown in an orientation before the thermal component 340 is attached to the blank module 322.

While FIG. 3 shows a thermal component 340 extending across a portion of a blank module 322 (e.g., about half of the length of the corresponding memory module), one of ordinary skill in the art would understand the thermal inserts 340 may extend across any or all of the corresponding blank module 322. Additionally, while FIG. 3 shows a thermal component 340 positioned to modify the air flow on a latter side of the air flow across the blank module 322, one of ordinary skill in the art would understand the thermal inserts 340 could be positioned to modify the air flow anywhere across the corresponding blank module 322 (e.g., on an early side of the air flow, at a midway location of the air flow or across all of the corresponding blank module 322). Accordingly, the blank module 322 may be positioned to align and constrain a thermal component 340 during installation and normal use of the memory modules such that thermal component 340 may avoid touching and/or damaging adjacent memory modules 320.

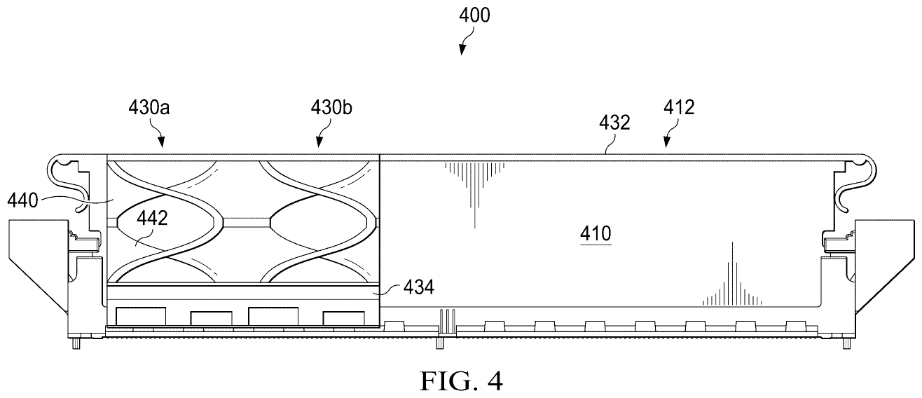

FIG. 4 shows side view of a blank system 400. In certain embodiments, the blank system 400 corresponds to the blank module of the memory system 150. In certain embodiments, the blank system 400 includes a blank component 410 and an integrated air flow component 412. In certain embodiments, the blank component 410 is configured with a form factor which substantially (i.e. +/−10%) corresponds to the form factor of the memory modules of the memory system. In certain embodiments, the blank component 410 is configured with substantially (i.e. +/−10%) the same size and shape as the memory modules of the memory system. In certain embodiments, the blank component 410 is configured with substantially (i.e. +/−10%) the same size and shape as a DIMM module. In certain embodiments, the blank component 410 is configured to attach to a connector receptacle of a mount system such as mount system 200.

In certain embodiments, the integrated thermal component 404 is integrated into a blank module of a mount system. In certain embodiments, such an integrated thermal component expands a thermal component implementation to include a thermal component implementation which can be provided via a system supplier, a blank vendor, a thermal solutions provider, etc. In certain embodiments, the integrated air flow component 404 includes an integrated air flow geometry. In certain embodiments, the air flow geometry includes a spiraling air flow geometry.

In certain embodiments, the integrated air flow component 412 includes a plurality of air flow directing components 430, a blank mount portion 432, a bottom portion 434, or a combination thereof. In certain embodiments, the plurality of air flow direction components 430 are configured to generate a spiraling air flow as cooling air flows across the thermal component. In certain embodiments, the blank mount portion 432 laterally extends across a top of the integrated air flow component 412. In certain embodiments, some or all of the blank mount portion 432 extends across a top of the plurality of air flow directing components 430. In certain embodiments, the blank mount portion 432 mechanically attaches the integrated air flow component 412 to the blank component 410. In certain embodiments, the bottom portion 434 extends across a bottom of the plurality of air flow directing components 430.

In certain embodiments, the thermal component 412 is integrated with the blank component 410 itself. In certain embodiments, the thermal component 412 is molded or attached to the blank component. In certain embodiments, the thermal component 412 may be offered as a thermal high-performance connector product by a system supplier, a blank vendor, a thermal solutions provider, etc. In certain embodiments, the thermal component 412 is provided to be attached by a consumer to the blank module itself.

In various embodiments, the thermal component is molded into, attached to, or attachable to a body of the blank module. In certain embodiments, the thermal component can be offered as a thermal high-performance product from a system supplier, a blank vendor, a thermal solutions provider, etc. In certain embodiments, the thermal component can be attached before or after memory modules are installed in a mount system. Providing such an attachment option facilitates future upgraded air flow components, an easy ability to accommodate memory module pitch variations and allows repairability in the field or factory.

In various embodiments, the thermal component can be implemented on either or both sides of the blank module. In various embodiments, thermal component configuration provides an ability to add double sided cooling to memory locations that previously could not have had coverage on both sides of the memory components.

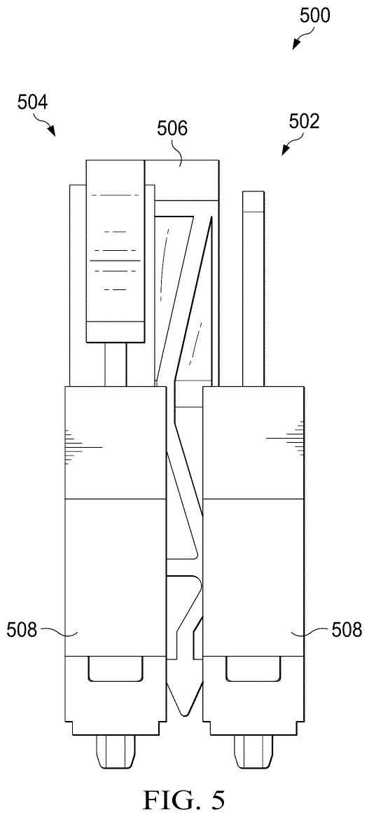

FIG. 5 shows a side view of a mount system 500 configured with a memory module 502 and a blank module 504 with an integrated air flow component 506. In certain embodiments, the memory module 502 and the blank module 504 are mounted to respective connector receptacles 508. In certain embodiments, the connector receptacles 508 correspond to slots 162. In certain embodiments, the memory module 502 corresponds to a memory module 160.

In various embodiments, the thermal components 506 can be implemented on either or both sides of the blank module 504. In various embodiments, the thermal component configuration provides an ability to add double sided cooling to memory locations that previously could not have had coverage on both sides of the memory components. In certain embodiments, the thermal component 508 is mechanically attached to a respective blank module 504.

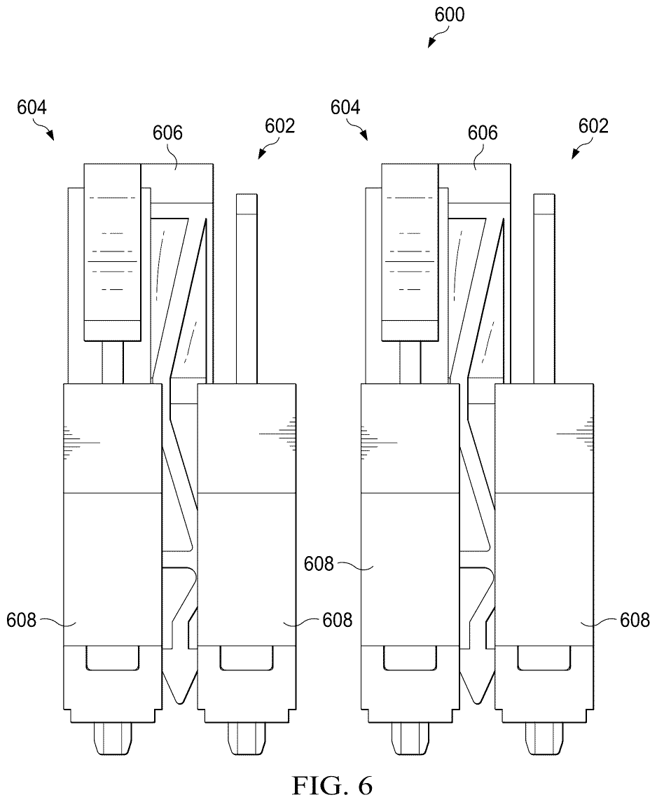

FIG. 6 shows a side view of a mount system 600 configured with a memory module 602 and a blank module 604 with an integrated air flow component 606. In certain embodiments, the memory module 602 and the blank module 604 are mounted to respective connector receptacles 608. In certain embodiments, the connector receptacles 608 correspond to slots 162. In certain embodiments, the memory module 602 corresponds to a memory module 160.

In certain embodiments, a thermal component 608 is mechanically attached to a respective blank module 604. In various embodiments, the thermal components 606 can be implemented on a right side of the blank module 604. By so mounting the thermal components 606, cooling is provided to a left side of a memory module 602. In certain embodiments, by so mounting the thermal components 606, the memory modules 602 are cooled without needing a thermal component mounted to the memory module 602.

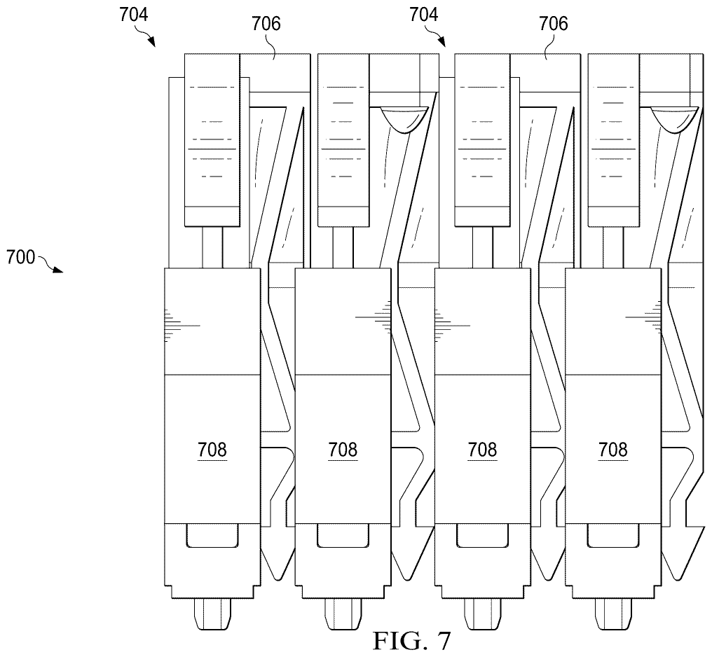

FIG. 7 shows a side view of a mount system 700 configured with a memory module 702 with an integrated air flow component 706 and a blank module 704 with an integrated air flow component 706. In certain embodiments, the memory module 702 and the blank module 704 are mounted to respective connector receptacles 708. In certain embodiments, the connector receptacles 708 correspond to slots 162. In certain embodiments, the memory module 702 corresponds to a memory module 160.

In certain embodiments, the thermal components 708 are mechanically attached to respective memory modules 702 and respective blank modules 604. In various embodiments, the thermal components 706 can be implemented on a right side of a memory module 702. In various embodiments, the thermal components 706 can be implemented on a right side of the blank module 704. By so mounting the thermal components, cooling is provided to both sides of a memory module.

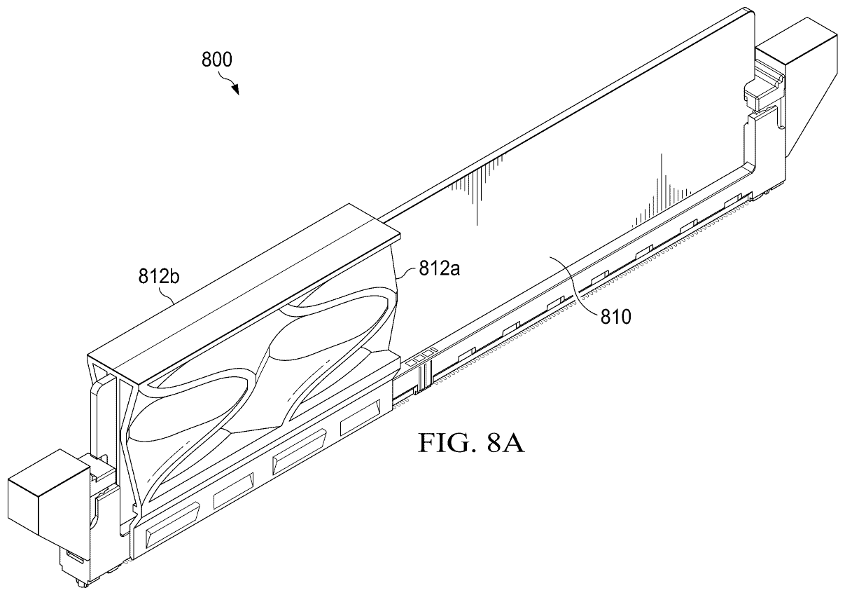

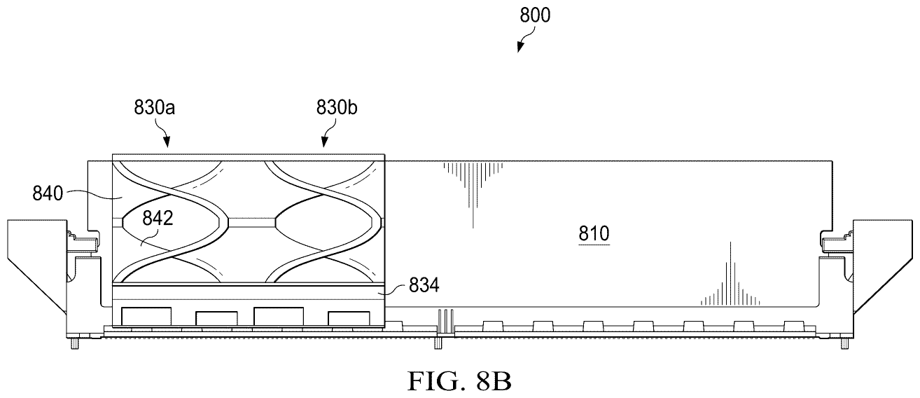

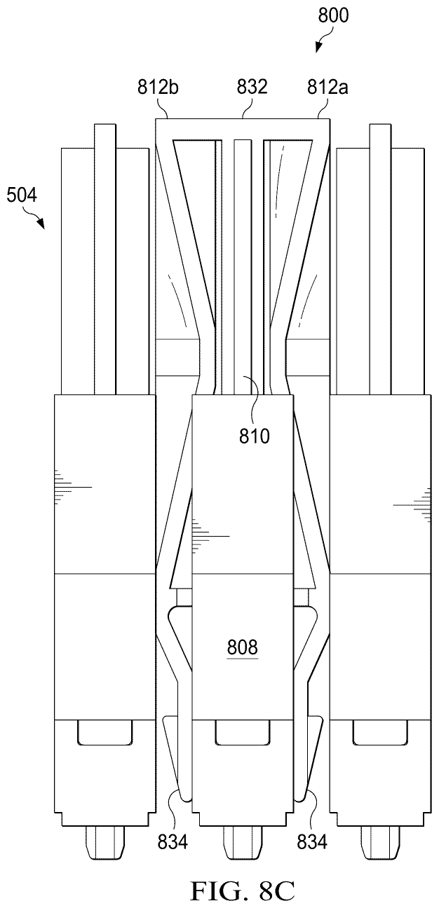

FIGS. 8A, 8B and 8C, generally referred to as FIG. 8, show views of a blank system 800. In certain embodiments, the blank system 800 corresponds to the blank module of the memory system 150. In certain embodiments, the blank system 800 includes a blank component 810, a first side integrated air flow component 812a, a second side air flow component 812b, or a combination thereof. In certain embodiments, the blank component 810 is configured with a form factor which substantially (i.e. +/−10%) corresponds to the form factor of the memory modules of the memory system. In certain embodiments, the blank component 810 is configured with substantially (i.e. +/−10%) the same size and shape as the memory modules of the memory system. In certain embodiments, the blank component 810 is configured with substantially (i.e. +/−10%) the same size and shape as a DIMM module. In certain embodiments, the blank component 810 is configured to attach to a connector receptacle of a mount system such as mount system 200.

In certain embodiments, the integrated thermal components 812 are integrated into a blank module of a mount system. In certain embodiments, such integrated thermal components expand a thermal component implementation to include a thermal component implementation which can be provided via a system supplier, a blank vendor, a thermal solutions provider, etc. In certain embodiments, the integrated air flow components 812 include an integrated air flow geometry. In certain embodiments, the air flow geometry includes a spiraling air flow geometry.

In certain embodiments, the integrated air flow component 812 includes a plurality of air flow directing components 830, a blank mount portion 832, a bottom portion 834, or a combination thereof. In certain embodiments, the plurality of air flow direction components 830 are configured to generate a spiraling air flow as cooling air flows across the thermal component. In certain embodiments, the blank mount portion 832 laterally extends across a top of the integrated air flow component 812. In certain embodiments, some or all of the blank mount portion 832 extends across a top of the plurality of air flow directing components 830. In certain embodiments, the blank mount portion 832 mechanically attaches the integrated air flow component 812 to the blank component 810. In certain embodiments, the bottom portion 834 extends across a bottom of the plurality of air flow directing components 830.

In certain embodiments, one or more thermal components 812 are configured with the blank component 810 as a single piece of material. In certain embodiments, one or more thermal components 812 are molded with the blank component. In certain embodiments, the blank system 800 may be offered as a thermal high-performance connector product by a system supplier, a blank vendor, a thermal solutions provider, etc.

In certain embodiments, the blank system 800 can be offered as a thermal high-performance product from a blank vendor. In certain embodiments, the blank system 800 can be attached before or after memory modules are installed in a mount system. Providing such an attachment option facilitates future upgraded air flow components, an easy ability to accommodate memory module pitch variations and allows repairability in the field or factory.

In various embodiments, the integrated air flow components 810 can be implemented on either or both sides of the blank module 810. In various embodiments, integrated air flow component configuration provides an ability to add double sided cooling to memory locations that previously could not have had coverage on both sides of the memory components.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A blank system for use with a memory system of an information handling system, comprising:
a blank module, the module being configured to mount to a connector receptacle of a memory mount system; and,
an integrated thermal component mechanically attached to the blank module, the integrated thermal component being positioned to avoid touching a memory module when the memory module is installed in the mount system.

2. The blank system of claim 1, wherein:
the integrated thermal component includes an air flow directing component and a mount portion, the mount portion extending laterally across the air flow directing component.

3. The blank system of claim 2, wherein:
the integrated thermal component is mechanically attached to the blank module via the mount portion.

4. The blank system of claim 2, wherein:
the integrated thermal component includes a plurality of air flow directing components; and,
the mount portion extends laterally across a top of the plurality of air flow directing components.

5. The blank system of claim 1, wherein:
the integrated thermal component is molded into, attached to, or attachable to the blank module.

6. The blank system of claim 1, wherein:
the blank module and the integrated thermal component are configured to be attached by a consumer to the mount system.

7. A mount system comprising:
a plurality of connector receptacles, each of the plurality of connector receptacles being configured to receive a respective memory module, the plurality of connector receptacles being positioned to arrange the respective memory modules in an array; and,
a blank system, the blank system comprising
a blank module, the module being configured to mount to a connector receptacle of the plurality of connector receptacles; and,
an integrated thermal component mechanically attached to the blank module, the integrated thermal component being positioned to avoid touching a memory module when the memory module is installed in the mount system.

8. The mount system of claim 7, wherein:
the integrated thermal component includes an air flow directing component and a mount portion, the mount portion extending laterally across the air flow directing component.

9. The mount system of claim 8, wherein:
the integrated thermal component is mechanically attached to the blank module via the mount portion.

10. The mount system of claim 8, wherein:
the integrated thermal component includes a plurality of air flow directing components; and,
the mount portion extends laterally across a top of the plurality of air flow directing components.

11. The system of claim 7, wherein:
the integrated thermal component is molded into, attached to, or attachable to the blank module.

12. The system of claim 7, wherein:
the blank module and the integrated thermal component are configured to be attached by a consumer to the mount system.

13. A system comprising:
a processor;
a data bus coupled to the processor; and
a mount system coupled to the processor via the data bus, the mount system comprising:
a plurality of connector receptacles, each of the plurality of connector receptacles being configured to receive a respective memory module, the plurality of connector receptacles being positioned to arrange the respective memory modules in an array; and,
a blank system, the blank system comprising
a blank module, the module being configured to mount to a connector receptacle of the plurality of connector receptacles; and,
an integrated thermal component mechanically attached to the blank module, the integrated thermal component being positioned to avoid touching a memory module when the memory module is installed in the mount system.

14. The system of claim 13, wherein:
the integrated thermal component includes an air flow directing component and a mount portion, the mount portion extending laterally across the air flow directing component.

15. The system of claim 14, wherein:
the integrated thermal component is mechanically attached to the blank module via the mount portion.

16. The system of claim 14, wherein:
the integrated thermal component includes a plurality of air flow directing components; and,
the mount portion extends laterally across a top of the plurality of air flow directing components.

17. The system of claim 13, wherein:
the integrated thermal component is molded into, attached to, or attachable to the blank module.

18. The system of claim 13, wherein:
the blank module and the integrated thermal component are configured to be attached by a consumer to the mount system.
